(19) United States
(12) Patent Application Publication
(10) Pub. No.: US 2024/0079457 A1
(43) Pub. Date: Mar. 7, 2024

(54) METHOD FOR MANUFACTURING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventors: Jun WEI, Hefei (CN); Huan XIA, Hefei (CN); Yihang WANG, Hefei (CN); Dong YAN, Hefei (CN); Jia KANG, Hefei (CN); Wei LI, Hefei (CN)

(21) Appl. No.: 18/169,996

(22) Filed: Feb. 16, 2023

(30) Foreign Application Priority Data
Sep. 7, 2022 (CN) 202211091286.X

(51) Int. Cl. H01L 29/40; H01L 21/285; H01L 29/417

(52) U.S. Cl. CPC H01L 29/401; H01L 21/28518; H01L 29/41766

(57) ABSTRACT

The method for manufacturing the semiconductor structure includes: providing a substrate, and forming contact holes in the substrate; depositing a metal at a bottom of each contact hole, and performing a reverse sputtering treatment to form a metal layer; in the reverse sputtering treatment, metal atoms or metal ions are sputtered onto at least a part of a side wall of each contact hole; performing a annealing treatment, to cause the substrate reacts with the metal layer to form a metal silicide layer.

### CROSS-REFERENCE TO RELATED APPLICATION

The present application claims benefit of Chinese Patent Application No. 202211091286.X, filed on Sep. 7, 2022, the contents of which are hereby incorporated by reference in its entirety.

### TECHNICAL FIELD

The disclosure belongs to the field of semiconductors, and particularly relates to a method for manufacturing a semiconductor structure and a semiconductor structure.

### BACKGROUND

A Dynamic Random Access Memory (DRAM) is a semiconductor memory, the main principle of action of which is to represent whether a stored binary bit is 1 or 0 by the amount of charge stored in a capacitor.

When the feature size of a semiconductor process is reduced to magnitude lower than sub-micron, the size of internal structures of the memory is also reduced correspondingly, and the equivalent series resistance of these internal structures is increased, which affects the speed of a circuit. That is, the delay time of the DRAM is relatively long, and the operation speed of the DRAM needs to be improved.

### SUMMARY

In an aspect, a method for manufacturing a semiconductor structure is provided, which includes the operations of: providing a substrate, and forming contact holes in the substrate; depositing a metal at a bottom of each contact hole, and performing a reverse sputtering treatment to form a metal layer; in the reverse sputtering treatment, metal atoms or metal ions are sputtered onto at least a part of a side wall of each contact hole; and performing a annealing treatment, to cause the substrate reacts with the metal layer to form a metal silicide layer.

In another aspect, a semiconductor structure is provided, which includes: a substrate in which contact holes are formed; and a metal silicide layer formed in each contact hole, the metal silicide layer has a concave shape and covers a bottom of the contact hole and at least a part of a side wall of the contact hole.

### BRIEF DESCRIPTION OF THE DRAWINGS

The accompanying drawings, which are incorporated in and constitute a part of this specification, illustrate the embodiments consistent with the disclosure and, together with the specification, serve to explain the principles of the disclosure. Obviously, the drawings described below are only some embodiments of the disclosure, and other drawings can further be obtained by those of ordinary skill in the art according to the drawings without creative work.

FIGS. 1-2 illustrate schematic views corresponding to steps in a method for manufacturing a semiconductor structure.

FIGS. 3-15 illustrate schematic views corresponding to steps in a method for manufacturing a semiconductor structure provided by an embodiment of the disclosure.

### DETAILED DESCRIPTION

As known in the background art, the delay time of the DRAM is relatively long, and the operation speed of the DRAM needs to be improved. Detailed description will be made below.

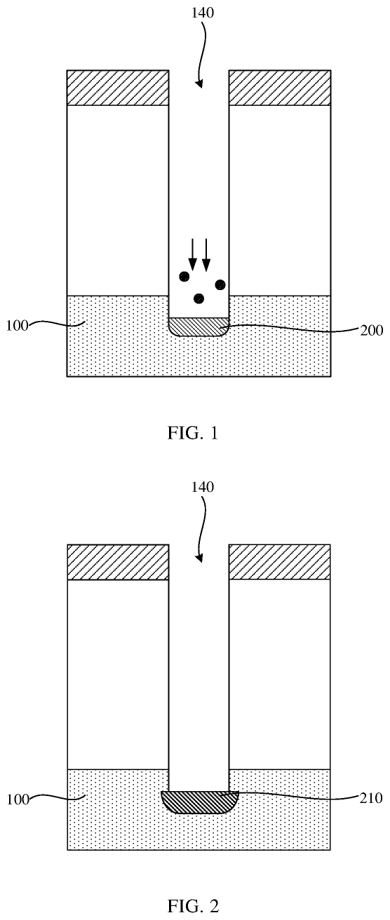

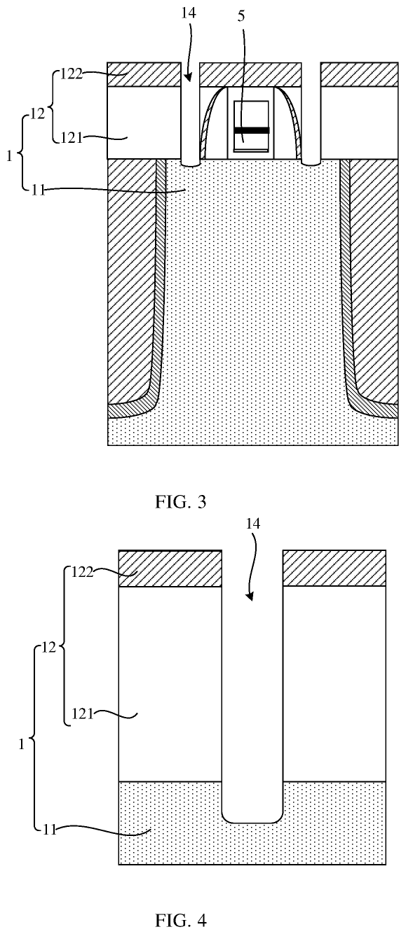

In order to reduce contact resistance, a metal silicide process technology has been developed and applied to a semiconductor manufacturing process. A metal silicide is a metal compound formed by a chemical reaction between a metal and silicon, and has a conductive property intermediate between conductive properties of the metal and silicon. Referring to FIGS. 1-2, a semiconductor structure includes a silicon substrate 100. Structures such as a source and a drain are disposed in the silicon substrate 100. Therefore, it is necessary to form contact holes 140 in the substrate 100 and fill the contact holes 140 with a conductive material to lead out the structures such as the source and the drain in the silicon substrate 100. Specifically, referring to FIG. 1, a metal layer 200 is deposited at the bottom of the contact hole 140. Referring to FIG. 2, annealing treatment is performed to the metal layer 200 to form a metal silicide layer 210. As known from FIG. 2, as the feature size of a semiconductor process continuous to reduce, the size of the contact hole 140 continuous to reduce, and the contact resistance of each contact hole 140 continuous to reduce. Although the metal silicide layer 210 is formed, the top surface of the metal silicide layer 210 is relatively flat, and the contact area between the metal silicide layer 210 and the substrate 100 is small. It is to be noted that negative correlation exists between the contact resistance and the contact area between the metal silicide layer 210 and the silicon substrate 100, that is, the smaller the effective contact area, the higher the contact resistance. According to the RC delay effect, a larger contact resistance may affect the operation speed of the semiconductor structure.

The embodiments of the disclosure provide a method for manufacturing a semiconductor structure, in which: metal is deposited at the bottom of the contact hole, and reverse sputtering treatment is performed to form a metal layer. In the reverse sputtering treatment, metal atoms or metal ions are sputtered onto at least part of the side wall of the contact hole. That is, the metal layer covers not only the bottom of the contact hole but also the side wall of the contact hole. Therefore, the contact area between the metal layer and the substrate is relatively large, that is, the contact area between the metal silicide layer formed by the annealing treatment and the substrate is relatively large, so that the contact resistance is reduced to improve the operation rate of the semiconductor structure.

The embodiments of the disclosure will be described in detail below with reference to the drawings. However, it will be appreciated by those of ordinary skill in the art that in the embodiments of the disclosure, numerous technical details are set forth in order to provide a better understanding of the embodiments of the disclosure. However, the technical solutions claimed in the embodiments of the disclosure may be implemented even without these technical details and various changes and modifications based on the following embodiments.

As shown in FIGS. 3-15, an embodiment of the disclosure provides a method for manufacturing a semiconductor structure. The method for manufacturing the semiconductor structure will be described in detail below with reference to the drawings. It is to be noted that, for convenience of description and clarity of illustrating operations of the method for manufacturing the semiconductor structure, FIGS. 3-15 are partial schematic views of the semiconductor structure.

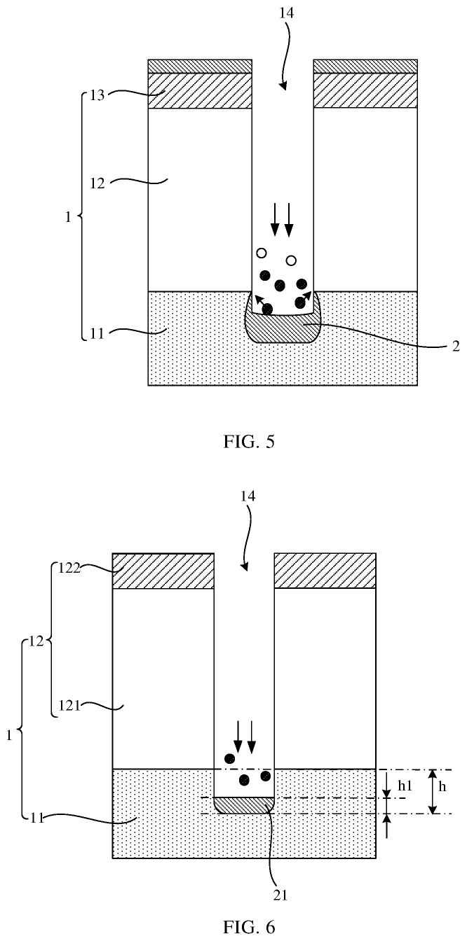

Referring to FIGS. 3-4 (FIG. 4 is a partial enlarged view of FIG. 3), a substrate 1 is provided, and contact holes 14 are formed in the substrate 1. In an example, the substrate 1 is dry-etched to form the contact holes 14.

In some embodiments, the substrate 1 includes a stack of a silicon substrate 11 and a dielectric layer 12; and the contact hole 14 passes through the dielectric layer 12 and extends into the silicon substrate 11. That is, the bottom of the contact hole 14 is located in the silicon substrate 11. The silicon substrate 11 may include active areas, that is, the silicon substrate 11 may have a source and a drain of a transistor therein. A metal silicide layer 6 formed later is electrically connected to the source and the drain.

In addition, the dielectric layer 12 may have a gate 5 of the transistor therein. The dielectric layer 12 may include a stack of a first dielectric layer 121 and a second dielectric layer 122, the first dielectric layer 121 may be made of silicon oxide, and the second dielectric layer 122 may be made of silicon nitride or silicon oxynitride. The dielectric layer 12 can isolate and protect the gate 5 from short circuit or leakage.

Referring to FIGS. 5-10, metal is deposited at the bottom of the contact hole 14, and reverse sputtering treatment is performed to form a metal layer 2. In the reverse sputtering treatment, metal atoms or metal ions are sputtered onto at least a part of the side wall of the contact hole 14. That is, the reverse sputtering treatment can change the shape of the metal layer 2 such that the metal layer 2 has a concave shape to contact a part of the side wall of the bottom of the contact hole 14, thereby increasing the contact area between the metal layer 2 and the substrate 1. The above operations will be exemplified below.

In the first example, referring to FIG. 5, an in-situ reverse sputtering process is adopted to simultaneously deposit metal and perform the reverse sputtering treatment. It is to be noted that the in-situ reverse sputtering process can change the shape of the metal attached to the substrate 1 while the metal is deposited. Therefore, the concave metal layer 2 can be formed by one process, so that the production process is simplified, and the production cost is reduced. In an example, cobalt, titanium or nickel platinum alloy can be used as a target material.

In the in-situ reverse sputtering process, plasma is used to bombard the surface of the target material. Metal atoms or metal ions on the surface of the target material obtain enough energy due to collision to finally escape from the surface of the target material, and is deposited in the contact hole 14. In addition, in the deposition process of the metal atoms or metal ions to the contact hole 14, plasma can be adopted to etch a metal film deposited in the contact hole 14, and therefore, the morphology of the metal film is changed. That is, the metal atoms or metal ions are transferred from the bottom of the contact hole 14 to the side wall of the contact hole 14 after obtaining enough energy. It can be seen that the in-situ reverse sputtering process includes two processes. A first process is a process in which metal atoms or metal ions of the target material are deposited towards the contact hole 14. A second process is a process in which metal atoms or metal ions deposited at the bottom of the contact hole 14 are sputtered towards the side wall of the contact hole 14. The small black spheres in FIG. 5 are used to represent the metal atoms or metal ions, and the arrows in FIG. 5 are used to represent the direction of transfer of the metal atoms or metal ions. The small white spheres in FIG. 5 are used to represent plasma.

For example, the plasma may include positively charged inert gas ions, such as argon ions. Under the action of an external power supply, argon is ionized, so that glow discharge is generated, and positive argon ions bombard the target material. In addition, the argon ions also etch the deposited metal film in the contact hole 14.

In the in-situ reverse sputtering process, both of a direct-current sputtering and an alternating-current sputtering are adopted. It is to be noted that direct-current sputtering utilizes a direct-current power supply, while radio-frequency sputtering utilizes an alternating-current power supply. The speed of direct-current sputtering is high, and metal can be rapidly deposited in the contact hole 14. In alternating-current sputtering, only half of a cycle has cation flow, so that the deposition rate is low. However, the stability of radio-frequency sputtering is better, and the technological process is easier to control. Therefore, through a combination of direct current and alternating current, the deposition rate of the metal atoms is higher, and therefore, the reverse sputtering treatment can be carried out during the deposition.

In some embodiments, the power of the direct-current power supply is lower than that of the alternating-current power supply. Therefore, the stability of sputtering can be improved while the sputtering efficiency is guaranteed. In an example, the direct-current power is 400-500 W, and the radio-frequency power is 4000-5000 W. For example, the direct-current power may be 420 W, 450 W or 480 W, and the radio-frequency power may be 4300 W, 4600 or 5000 W. When the direct-current power and the radio-frequency power are kept in the above range, the quality of the metal layer 2 can be improved, and the defects of the metal layer 2 can be reduced.

In some embodiments, the process time of the in-situ reverse sputtering process may be 4-6 s, such as 5 s. It will be appreciated that if the process time is too long, the thickness of the metal layer 2 is too large, and the space available for a subsequently formed contact layer 4 may be occupied by the excessive thickness of the metal layer. If the process time is too short, the contact area of the metal layer 2 between the contact hole 14 may be reduced. When the process time is kept in the above range, the two problems may be both considered.

In some embodiments, the bias power of the in-situ reverse sputtering process is 100-300 W, for example, 200 W, 220 W or 290 W. The principle of action of bias voltage will be described in detail below.

The bias voltage here is a bias voltage applied near the surface of the substrate 1, and the bias voltage is generally a negative voltage. After plasma bombardment, target material sputtering occurs in two situations. In the first situation, the metal atoms of the target material escape from the surface of the target material, and these metal atoms are directly deposited on the surface of the substrate 1 to form a film. In the second situation, bombardment of the plasma may cause ionization of the atoms of the target material, typically positive ions is escaped. The ionized ions are the main object of action of bias voltage.

Under the action of bias voltage, sputtered ions obtain kinetic energy, accelerate to fly to the substrate 1 and bombard the surface of the substrate 1. In such a case, atoms which are not firmly combined with the surface of the substrate 1 can be knocked off, so that some film atoms which are tightly combined and have few defects are retained, and therefore, the film quality is improved. In addition, bias voltage may also attract a part of argon ions, and the bombardment of the argon ions can generate a cleaning effect on impurities on the surface of the inner wall of the contact hole 14. In addition, the increase of energy will also cause a part of metal atoms to be driven into the substrate 1 but not only adsorbed on the surface layer of the substrate 1. Thus, the porosity of the film is reduced, the compactness is improved, and a film with lower roughness can be obtained.

The reverse sputtering phenomenon arises as the bias voltage increases further. Although the reverse sputtering phenomenon may reduce the deposition rate, the purpose of changing the morphology of the film can be achieved, so that the contact area of between the metal layer 2 and the contact hole 14 is increased.

When the bias power of the in-situ reverse sputtering process is 100-300 W, it is beneficial to improve the film forming quality, meanwhile, it is guaranteed that more metal atoms or metal ions are attached to the side wall of the contact hole 14, thereby increasing the contact area between the metal layer 2 and the contact hole 14.

In second example, referring to FIGS. 6-10, metal is deposited at the bottom of the contact hole 14 to form a metal film 21; and reverse sputtering treatment is performed to the metal film 21 after the metal film 21 is formed. That is, a deposition process is performed at first, and then reverse sputtering treatment is performed. In this way, it is advantageous to improve the quality of the metal layer 2, and to achieve a better concave morphology.

Specifically, referring to FIG. 6, metal is deposited at the bottom of the contact hole 14 by a physical vapor deposition process. Radio-frequency deposition is mainly used in the deposition process. The power of the direct-current power supply is lower than that of the direct-current power supply. A Capacitively Coupled Plasma (CCP) is generated by the alternating-current power supply and direct-current power supply, and metal is deposited under the control of magnetic field to form the metal film 21. The uniformity of the metal film 21 formed by CCP is good, and the ionization capacity is easier to adjust.

In an example, the power of the alternating-current power supply is 4000-5000 W, such as 4300 W, 4500 W or 4900 W. The power of the direct-current power supply is 300-400 W, such as 310 W, 360 W or 370 W.

It is to be noted that, the physical vapor deposition process in the second example uses lower direct-current frequency than the direct-current frequency in the in-situ reverse sputtering process in first example. The main reason lies in that: in first example, since more metal atoms need to be provided in the deposition process to guarantee the generation of the reverse sputtering phenomenon, the larger direct-current frequency is adopted to accelerate the deposition rate. In second example where the reverse sputtering treatment is performed after the metal film 21 is formed, and the content of metal atoms is sufficient. In this case, in order to improve the stability of the process, a direct-direct power supply with a relatively low power can be used.

In some embodiments, the duration of the physical vapor deposition process can be 7 s, that is, the duration of the physical vapor deposition process in second example can be longer than that of the in-situ reverse sputtering treatment in first example. As described above, the direct-current frequency and deposition rate of the physical vapor deposition process is low, so that the process duration may be appropriately increased to meet the thickness requirement of the metal film 21.

In some embodiments, the ratio of the thickness h1 of the metal film 21 to the depth h of the contact hole 14 in the silicon substrate 11 is 1/3-3/7, such as 8/21. It is to be noted that if the metal film 21 is too thin, it may be difficult to provide sufficient metal atoms for the reverse sputtering process to form the metal layer 2 with ideal morphology. If the metal layer 2 is too thick, the space available for the subsequently formed contact layer 4 may be occupied by the metal layer. In addition, if the contact hole 14 in the silicon substrate 11 is too deep, the problem lies in that, it may be difficult to fill the contact hole with the metal film 21 of sufficient thickness; and if the contact hole 14 in the silicon substrate 11 is too shallow, the problem lies in that, a part of the metal atoms may be sputtered onto the side surface of the dielectric layer 12. When the ratio of the thickness h1 of the metal film 21 to the depth h of the contact hole 14 located in the silicon substrate 11 is in the above range, the problems can be reconciled, and therefore, the metal silicide is prevented from being formed on the side surface of the dielectric layer 12 while a relatively large contact area between the metal layer 2 and the silicon substrate 11 is ensured.

For example, the thickness of the metal film 21 may be 3-5 nm, such as 4 nm. When the thickness of the metal film 21 is in the above range, more metal atoms or metal ions can be sputtered onto the side wall of the contact hole 14, and sufficient space can be provided for the subsequently formed contact layer 4.

In some embodiments, the reverse sputtering treatment includes a first reverse sputtering treatment and a second reverse sputtering treatment. The use of two reverse sputtering treatment processes is beneficial to increase of metal atoms sputtered to the side wall of the contact hole 14, so that the contact area between the metal layer 2 and the contact hole 14 is increased.

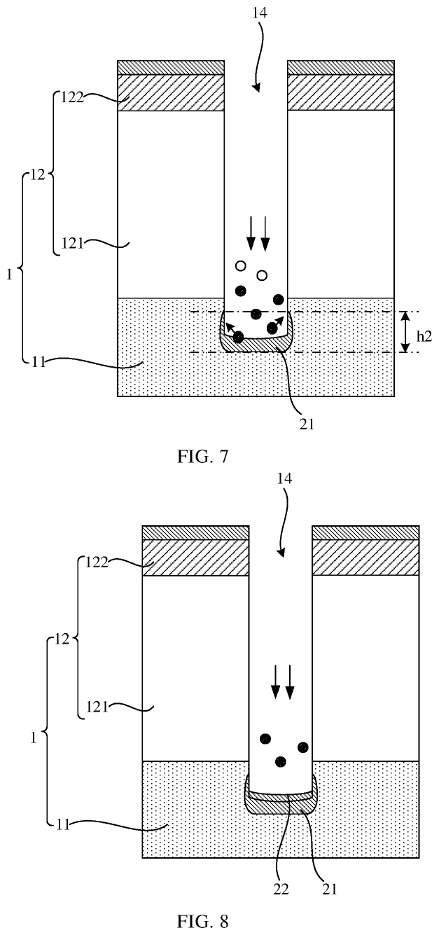

Specifically, referring to FIG. 7, the first reverse sputtering treatment is performed to the metal film 21. It is to be noted that, during the first reverse sputtering treatment, metal atoms or metal ions may be provided to bombard the metal film 21. Therefore, a thin layer of metal atoms may be retained on the surface of the metal film 21 after the first reverse sputtering treatment.

Comparing FIG. 6 with FIG. 7, it can be found that the thickness h2 of the metal film 21 on the side wall of the contact hole 14 after the first reverse sputtering treatment is increased, that is, the contact area is increased.

The first reverse sputtering process may use only the alternating-current power supply, but not use the direct-current power supply, namely, only radio-frequency sputtering is adopted. The main reason is that, the metal film 21 has been formed before the first reverse sputtering process, and the bottom of the contact hole 14 has enough metal atoms for sputtering to the side wall of the contact hole 14. Therefore, in order to improve the reliability of the first reverse sputtering treatment, the alternating-current power supply can no longer be used.

In addition, the radio-frequency power of the first reverse sputtering treatment may be 4000 W-5000 W, and the process duration may be 5 s. In this way, defects generated by the first reverse sputtering treatment can be reduced while the sputtering efficiency is guaranteed.

According to some embodiments, referring to FIG. 8, after the first reverse sputtering treatment and before the second reverse sputtering treatment, the method further includes an operation in which a first repairing layer 22 is formed on the surface of the metal film 21. In an example, a layer of metal atoms is deposited on the surface of the metal film 21 so as to complete self-repairing.

It is to be noted that the first repairing layer 222 can not only repair the defects generated by the first reverse sputtering treatment, but also can provide more metal atoms for the second reverse sputtering treatment, to increase the metal atoms sputtered onto the side wall of the contact hole 14.

In some embodiments, the first repairing layer 22 is deposited with a direct-current power of 300 W-400 W and a radio-frequency power of 4000-5000 W. Namely, the radio-frequency power is greater than the direct-current power, so that the controllability of the process is improved. In some embodiments, the time for depositing the first repairing layer 22 is 4-7 s, and the deposition thickness is 1-5 nm. Therefore, the quality of the first repairing layer 22 can be improved while ensuring the deposition speed.

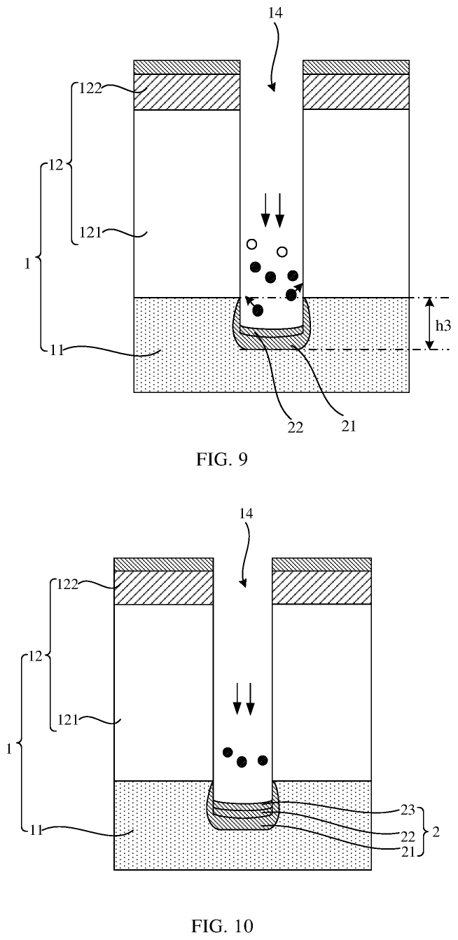

Referring to FIG. 9, the second reverse sputtering treatment is performed to the metal film 21 and the first repairing layer 22. Comparing FIG. 7 with FIG. 9, it can be found that the thickness h3 of the metal film 21 on the side wall of the contact hole 14 after the second reverse sputtering treatment is further increased.

In some embodiments, the bias power of the second reverse sputtering treatment is greater than that of the first reverse sputtering treatment. According to principle of action of bias voltage, the greater bias power in the second reverse sputtering treatment can enhance the degree of reverse sputtering, thereby increasing metal atoms sputtered onto the side wall of the contact hole 14. In addition, the thickness of the metal film 21 is lower than the total thickness of the metal film 21 and the first repairing layer 22, so that it is enough for the first reverse sputtering treatment to adopt small bias power to sputter the metal atoms or metal ions onto the surface of the metal film 21. Therefore, the damage to the film layer can be reduced while the sputtering degree is guaranteed.

In an example, the bias power of the first reverse sputtering treatment is 100-200 W, for example, 150 W, 170 W or 180 W. The bias power of the second reverse sputtering treatment is 200-300 W, for example, 220 W, 250 W or 280 W. It is to be noted that the difference value between the bias power of the second reverse sputtering treatment and the bias power of the first reverse sputtering treatment should not to be too large. If the difference value between the bias powers is too large, film defects may be increased, and the reverse sputtering efficiency may be reduced. When the bias power of the first reverse sputtering treatment and the bias power of the second reverse sputtering treatment are kept in the above range, the film quality can be guaranteed, and the process efficiency can be improved.

In some embodiments, the parameters of the second reverse sputtering treatment, such as duration and radio-frequency power, can be the same as those of the first reverse sputtering treatment. Specific reference may be made to the detailed description of the first reverse sputtering treatment, and the detailed description will not be repeated herein.

In some embodiments, referring to FIG. 10, after the second reverse sputtering treatment, the method further includes an operation in which a second repairing layer 23 covering the metal film 21 and the first repairing layer 22 is formed on the surface of the metal layer 2. The metal film 21, the first repairing layer 22 and the second repairing layer 23 form the metal layer 2. In an example, a thin layer of metal atoms is deposited on the surface of the second repairing layer 23 so as to complete self-repairing. That is, the second repairing layer 23 can repair defects generated by the second reverse sputtering treatment, so that the compactness of the metal layer 2 can be improved, and the roughness of the metal layer 2 can be reduced.

The process parameters for forming the second repairing layer 23 may be the same as the process parameters for forming the first repairing layer 22. Therefore, the process is simpler, and the production efficiency is higher. The process parameters for forming the second repairing layer 23 may be referred to in the foregoing detailed description.

In some embodiments, the thickness of the second repairing layer 23 and the thickness of the first repairing layer 22 may be smaller than that of the metal film 21. That is, the space occupied by the first repairing layer 22 and the second repairing layer 23 in the contact hole 14 are reduced while the repairing effect is guaranteed.

Based on the operations shown in FIGS. 3-10, the concave metal layer 2 can be formed at the bottom and on the side wall of the contact hole 14 by either the method of first example or the method of second example. Compared with the metal layer 2 having a flat top surface, the concave metal layer 2 can avoid occupying too much space in the contact hole 14, and meanwhile, a larger contact area with the silicon substrate 11 can be guaranteed.

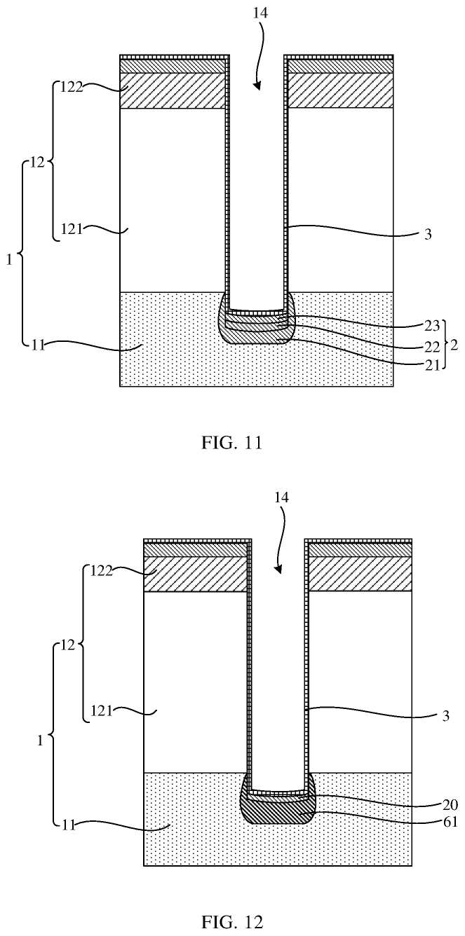

Referring to FIG. 11, a barrier layer 3 is formed on the side wall of the contact hole 14 and the surface of the metal layer 2. In an example, the barrier layer 3 can be made of titanium nitride, cobalt nitride or the like. The barrier layer 3 can block the diffusion of silicon during a subsequent annealing treatment, thereby reducing the risk of short circuit. Detailed description will be made below.

Referring to FIGS. 12 and 14, an annealing treatment is performed, so that the substrate 1 reacts with the metal layer 2, and a metal silicide layer 6 is produced. The metal silicide layer 6 can reduce the contact resistance between a subsequently formed contact layer 4 and the silicon substrate 11, thereby improving the operation rate of the semiconductor structure.

In an example, the annealing treatment is Rapid Thermal Annealing (RAT). Silicon will diffuse along the grain boundary of the metal silicide under the high-temperature condition of annealing treatment. The metal silicide can be prevented from overgrowing on the dielectric layer 12 under the action of the barrier layer 3. Namely, the barrier layer 3 can control the growth direction of the metal silicide, and the problems of bridging, electric leakage and the like are avoided.

In some embodiments, the annealing treatment includes first annealing treatment and second annealing treatment, the first annealing treatment is performed to the metal layer to form an initial metal silicide layer 61, and the second annealing treatment is performed to the initial metal silicide layer 61 to form the metal silicide layer 6. The temperature of the first annealing treatment is lower than that of the second annealing treatment. The first annealing treatment and the second annealing treatment will be described in detail below in connection with specific metal materials.

Specifically, referring to FIG. 12, first annealing treatment is performed to form an initial metal silicide layer 61. The first annealing treatment may have a lower temperature. If the metal layer 2 is a cobalt layer, the temperature of the first annealing treatment may be 350-400° C., such as 360° C., 370° C. or 390° C. The first annealing treatment causes cobalt metal to react with silicon to produce cobalt silicide (CoSi). During the first annealing treatment, cobalt is the dominating diffusor which enters the silicon substrate 11 to react with silicon.

In some other embodiments, the metal layer 2 is a titanium layer, then the first annealing treatment results in high-resistance dititanium silicide (Ti₂Si), which is of a body-centered orthorhombic structure, and belongs to a C49 mesophase. In the first annealing treatment process, titanium does not react with the silicon oxide material in the dielectric layer 12 to generate a metal silicide. In some other embodiments, the metal layer 2 is a nickel-platinum alloy, and Ni₂PtSi is obtained after the first annealing treatment.

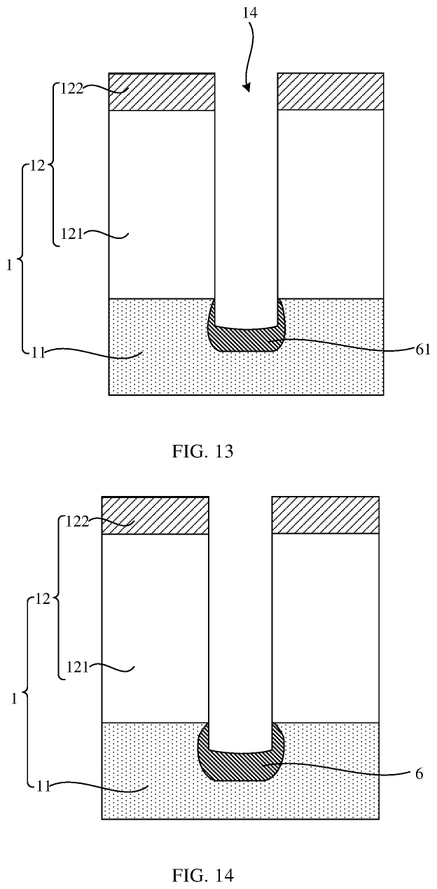

Referring to FIG. 13, after the first annealing treatment, the method further includes an operation in which an unreacted portion of the metal layer 20 is removed. That is, during the subsequent second annealing treatment, silicon atoms may diffuse to the side wall of the dielectric layer 12 and produce a metal silicide with the unreacted portion of the metal layer 20 in the first annealing treatment, and the metal silicide attached to the side walls of the dielectric layer 12 may cause a bridge short.

In an example, the metal layer 2 is removed by a wet etching process. The wet etching method is simple and high in efficiency. In addition, a reagent with a high selection etch ratio may be used, to reduce the damage to the initial metal silicide layer 61. For example, the reagent for wet etching may include ammonium hydroxide and hydrogen peroxide.

In addition, metal atoms in the barrier layer 3 can only react with silicon in the silicon substrate 11 and not react with silicon in the dielectric layer 12. Therefore, wet etching can also remove the unreacted portion of the barrier layer 3 on the surface of the dielectric layer 12 and the surface of the metal layer 2.

Referring to FIG. 14, second annealing treatment is performed, which may have

a higher temperature. If the metal layer 2 is a cobalt layer, the temperature of the second annealing treatment may be 600-700° C., such as 610° C., 650° C. or 680° C. The second annealing treatment transforms cobalt silicide (CoSi) into cobalt disilicide (CoSi₂). In this way, the contact resistance can be effectively reduced, since the resistance value of cobalt disilicide (CoSi₂) is lower than that of cobalt silicide (CoSi).

In some other embodiments, the metal layer 2 is a titanium layer, and then the second annealing treatment transforms dititanium silicide (Ti₂Si) in C49 phase to dititanium silicide in a low-resistance C54 phase, namely, titanium disilicide (TiSi₂). The C54 phase is of a face-centered orthorhombic system structure, which is good in thermodynamic property and high in stability. In some other embodiments, the metal layer 2 is a nickel platinum alloy, and the second annealing treatment transforms Ni₂PtSi to low-resistance NiPtSi₂.

The metal silicide technology of the above three materials will be described in the following.

When the feature size of the semiconductor structure is relatively large, the metal silicide technology using titanium can be adopted. Titanium disilicide (TiSi₂) has the advantages of being simple in process and good in high-temperature stability. However, as the thickness of the metal silicide layer 6 decreases or the line width decreases, a critical temperature at which the C49 phase is transformed into the C54 phase increases, and a critical temperature at which the C54 phase has agglomeration phenomena decreases. Thus, the phenomenon of agglomeration may occur in the metal silicide technology using titanium.

When the feature size of the semiconductor structure is relatively small, a metal silicide technology of cobalt or nickel platinum can be adopted. These two technologies can effectively avoid the agglomeration phenomenon directly. In addition, the metal silicide technology of nickel platinum may be selected for thermal concerns. The annealing temperature of the metal silicide technology of nickel platinum is lower. The lower annealing temperature may reduce damage to ultra-shallow junctions formed in a device. In addition, from the viewpoint of diffusion kinetics, a shorter annealing time can effectively suppress ion diffusion. Thus, spike anneal may be used for the first annealing treatment of the nickel platinum suicide. This annealing treatment only has a temperature rising process and temperature reducing process, but does not has a temperature preserving process, so that the diffusion degree of doping ions during the formation of the metal silicide can be limited.

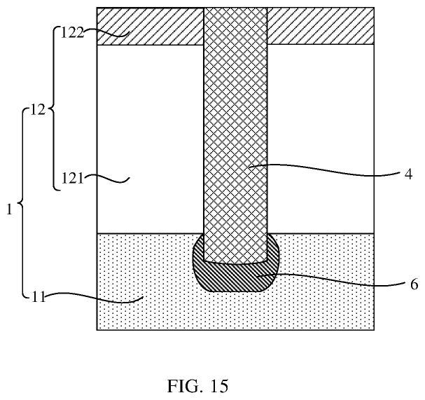

Referring to FIG. 15, a contact layer 4 filled in the contact hole 14 is formed, and the contact layer 4 covers the metal silicide layer 6. In an example, tungsten, copper, or the like is deposited in the contact hole 14 to form the contact layer 4. The concave morphology of the metal silicide layer 6 can increase the contact area between metal silicide layer and the contact layer 4, thereby reducing contact resistance.

In summary, in the embodiment of the disclosure, reverse sputtering treatment is performed to transfer a part of the metal atoms from the bottom of the contact hole 14 to the side wall of the contact hole 14, so as to form the metal layer 2 with a high contact area (HCA), and the annealing treatment can form a low-resistance metal silicide. Because the ohmic contact area is increased, the contact resistance between the contact layer 4 and the silicon substrate 11 can be reduced, and further, the electrical performance of the semiconductor structure can be improved.

In addition, after the reverse sputtering treatment, a thin layer of metal atoms can be deposited to repair the defects generated by the reverse sputtering treatment, thereby being beneficial to improving the compactness of the metal layer 2 and further improving the electrical property of the semiconductor structure.

In addition, metal does not react with the dielectric material, such as silicon oxide, silicon nitride, or silicon oxynitride, so the metal silicide can align with the active area.

As shown in FIG. 15, the embodiments of the disclosure further provide a semiconductor structure, which may be manufactured by the manufacturing method provided by the foregoing embodiment. For the detailed description of the semiconductor structure, reference is made to the foregoing detailed description, which is not repeated here.

Referring to FIG. 15, the semiconductor structure includes a substrate 1 in which contact holes 14 are formed. A metal silicide layer 6 is formed in the contact hole 14 and has a concave shape, and covers the bottom and at least a part of the side wall of the contact hole 14. That is, even if the inner diameter of the contact hole 14 is small, the concave metal silicide layer 6 can increase its contact area with the contact hole 14, thereby reducing RC delay and improving the operation rate of the semiconductor structure.

The semiconductor structure will be described in detail below.

In some embodiments, the semiconductor structure may be a DRAM. The metal silicide layer 6 can be formed in a peripheral area and can be in ohmic contact with the source and the drain. In some other embodiments, the metal silicide may also be in ohmic contact with the gate. The foregoing is merely exemplary illustration and the embodiments of the disclosure are not limited thereto.

In some embodiments, the metal layer 2 may be a cobalt layer, that is, the subsequently formed metal silicide layer 6 is cobalt disilicide. Compared with the metal silicide process using titanium, the metal silicide process using cobalt can effectively avoid the phenomenon of agglomeration. In addition, cobalt disilicide has a lower resistance than titanium disilicide; and with the size reduction, the resistance value of the cobalt silicide has smaller variation.

The semiconductor structure may further include: a contact layer 4 filled in the contact hole 14, and the contact layer 4 covers the metal silicide layer 6. The material of the contact layer 4 may be a low-resistance metal, thereby reducing RC delay and improving the operation rate of the semiconductor structure.

In some embodiments, the top surface of the metal silicide layer 6 located on the side wall of the contact hole 14 may be flush with the top surface of the silicon substrate 11, so that the contact area between the metal silicide layer 6 and the silicon substrate 11 can be effectively increased. In some other embodiments, the top surface of the metal silicide layer 6 located on the side wall of the contact hole 14 may also be slightly lower than the top surface of the silicon substrate 11, so that a larger filling space can be provided for the contact layer 4.

In summary, in the embodiments of the disclosure, the metal silicide layer 6 has a concave top surface, that is, the edge of the metal silicide layer 6 is higher than the middle part of the metal silicide layer 6, so that the contact area between the metal silicide layer 6 and the silicon substrate 11 can be increased to reduce the ohmic contact resistance, further reduce the RC delay, and improve the operation speed of the semiconductor structure.

In the descriptions of the specification, the descriptions made with reference to terms “some embodiments”, “In an example”, and the like refer to that specific features, structures, materials or characteristics described in combination with the embodiment or the example are included in at least one embodiment or example of the disclosure. In the specification, these terms are not always schematically expressed for the same embodiment or example. Moreover, the specific described features, structures, materials or characteristics may be combined in a proper manner in any one or more embodiments or examples. In addition, those skilled in the art may integrate and combine different embodiments or examples described in the specification and features of different embodiments or examples without conflicts.

The embodiments of the disclosure have been shown or described above. However, it can be understood that the abovementioned embodiments are exemplary and should not be understood as limits to the disclosure, and those of ordinary skill in the art may make variations, modifications, replacements and transformations to the abovementioned embodiments within the scope of the disclosure, it is therefore intended that all variations or modifications made in light of the claims and specification of the disclosure fall within the scope of the disclosure.

1. A method for manufacturing a semiconductor structure, comprising:
providing a substrate, and forming contact holes in the substrate;
depositing a metal at a bottom of each contact hole, and performing a reverse sputtering treatment to form a metal layer; in the reverse sputtering treatment, metal atoms or metal ions are sputtered onto at least a part of a side wall of each contact hole; and
performing an annealing treatment, to cause the substrate reacts with the metal layer to form a metal silicide layer.

2. The method for manufacturing the semiconductor structure of claim 1, wherein the depositing the metal at the bottom of the contact hole, and performing the reverse sputtering treatment to form the metal layer, comprises:
simultaneously depositing the metal and performing the reverse sputtering treatment by an in-situ reverse sputtering process.

3. The method for manufacturing the semiconductor structure of claim 2, wherein
in the in-situ reverse sputtering process, a direct-current power supply and an alternating-current power supply are provided, and power of the direct-current power supply is smaller than that of the alternating-current power supply.

4. The method for manufacturing the semiconductor structure of claim 3, wherein
the power of the direct-current power supply is 400-500 W, and the power of the alternating-current power supply is 4000-5000 W.

5. The method for manufacturing the semiconductor structure of claim 1, wherein the depositing the metal at the bottom of the contact hole, and performing the reverse sputtering treatment to form the metal layer, comprises:
depositing the metal at the bottom of the contact hole to form a metal film; and
after the metal film is formed, performing the reverse sputtering treatment to the metal film.

6. The method for manufacturing the semiconductor structure of claim 5, wherein
the reverse sputtering treatment comprises a first reverse sputtering treatment and a second reverse sputtering treatment which are performed in sequence; and
a bias power of the second reverse sputtering treatment is greater than that of the first reverse sputtering treatment.

7. The method for manufacturing the semiconductor structure of claim 6, wherein
the bias power of the first reverse sputtering treatment is 100-200 W, and the bias power of the second reverse sputtering treatment is 200-300 W.

8. The method for manufacturing the semiconductor structure of claim 6, wherein after the first reverse sputtering treatment and before the second reverse sputtering treatment, the method further comprises:
forming a first repairing layer on a surface of the metal film.

9. The method for manufacturing the semiconductor structure of claim 8, wherein after the second reverse sputtering treatment, the method further comprises:
forming a second repairing layer which covers the first repairing layer, wherein the metal film, the first repairing layer and the second repairing layer form the metal layer.

10. The method for manufacturing the semiconductor structure of claim 5, wherein
the substrate comprises a stack of a silicon substrate and a dielectric layer;
each contact hole passes through the dielectric layer and extends into the silicon substrate; and
a ratio of a thickness of the metal film to a depth of the contact hole in the silicon substrate is 1/3-3/7.

11. The method for manufacturing the semiconductor structure of claim 1, wherein before the annealing treatment, the method further comprises: forming a barrier layer on the side wall of each contact hole and a surface of the metal layer.

12. The method for manufacturing the semiconductor structure of claim 1, wherein the annealing treatment comprises first annealing treatment and second annealing treatment; the first annealing treatment is performed to the metal layer to form an initial metal silicide layer, and the second annealing treatment is performed to the initial metal silicide layer to form the metal silicide layer; and
a temperature of the first annealing treatment is smaller than that of the second annealing treatment.

13. The method for manufacturing the semiconductor structure of claim 12, wherein after the first annealing treatment and before the second annealing treatment, the method further comprises: removing unreacted metal layer.

14. The method for manufacturing the semiconductor structure of claim 1, wherein after the annealing treatment, the method further comprises:
forming a contact layer filled in each contact hole, with the contact layer covering the metal silicide layer.

15. A semiconductor structure, comprising:
a substrate in which contact holes are formed; and
a metal silicide layer formed in each contact hole, the metal silicide layer has a concave shape and covers a bottom of the contact hole and at least a part of a side wall of the contact hole.
